(19) United States
(12) Patent Application Publication
(10) Pub. No.: US 2025/0087635 A1
(43) Pub. Date: Mar. 13, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shu-Chuan CHI, Taichung City (TW); Yih-Jenn JIANG, Taichung City (TW); Cheng-Kai CHANG, Taichung City (TW); Huan-Shiang LI, Taichung City (TW); Yi-Chieh WANG, Taichung City (TW)

(73) Assignee: SILICONWARE PRECISION INDUSTRIES CO., LTD., Taichung City (TW)

(21) Appl. No.: 18/670,484

(22) Filed: May 21, 2024

(30) Foreign Application Priority Data
Sep. 13, 2023 (TW) 112134914

(51) Int. Cl. H01L 25/065; H01L 23/00; H01L 23/31; H01L 25/00

(52) U.S. Cl. CPC H01L 25/0652; H01L 23/3128; H01L 24/20; H01L 25/50; H01L 24/16; H01L 24/32; H01L 24/48; H01L 24/73; H01L 2224/16227; H01L 2224/21; H01L 2224/32145; H01L 2224/48227; H01L 2224/73253; H01L 2224/73265; H01L 2224/73267; H01L 2225/0651; H01L 2225/06517

(57) ABSTRACT

An electronic package and a manufacturing method thereof are provided, in which an electronic element stacking structure is disposed on a carrier structure to integrate multiple chips into a single package, so that the electronic package can meet with the requirements of miniaturization without increasing the layout area of the carrier structure.

### BACKGROUND

### 1. Technical Field

The present disclosure relates to a semiconductor packaging process, and more particularly, to an electronic package with stacked chips and a manufacturing method thereof.

### 2. Description of Related Art

With the evolution of semiconductor packaging technology, different packaging types have been developed for semiconductor devices. In order to improve electrical functions and save packaging space, different three-dimensional packaging technologies have been developed, such as fan-out package-on-package (FO PoP), to cope with the substantial increase in the number of input/output ports on various chips, and then integrate integrated circuits with different functions into a single packaging structure. This packaging method can give full play to system in a package (SiP) heterogeneous integration feature, which allows electronic elements with different functions, such as memory, central processing unit, graphics processor, imaging application processor, etc., to be integrated into the system by stacking design. It is suitable for applying in various thin and light electronic products.

FIG. 1 is a schematic cross-sectional view of a conventional semiconductor package 1. As shown in FIG. 1, the semiconductor package 1 comprises a packaging substrate 10 having at least one circuit layer 101, and a semiconductor element 11 bonded onto the circuit layer 101 by a flip-chip method.

Specifically, the semiconductor element 11 has an active surface 11a and an inactive surface 11b opposing the active surface 11a, and the active surface 11a has a plurality of electrode pads 110, so that the electrode pads 110 of the semiconductor element 11 are electrically connected to the circuit layer 101 via a plurality of solder bumps 12. Further, an underfill 13 is formed between the semiconductor element 11 and the circuit layer 101 to cover the solder bumps 12.

Moreover, in the semiconductor package 1, an encapsulant 15 is formed on the packaging substrate 10 to cover the underfill 13 and the semiconductor element 11, and a plurality of conductive vias 14 are formed in the encapsulant 15, so that end surfaces of the conductive vias 14 are exposed from the encapsulant 15 for subsequent connection with electronic devices such as semiconductor chips, silicon interposers, or packaging structures (not shown) via solder balls (not shown).

However, in the conventional semiconductor package 1, the exposed end surfaces of the conductive vias 14 are served as external contacts. Therefore, when the number of external contacts increases, the spacing between the conductive vias 14 needs to be reduced. At this time, bridge easily occurs between the solder balls on the end surfaces of the conductive vias 14.

Furthermore, if the conventional semiconductor package 1 requires more functions, more types of semiconductor elements 11 need to be disposed on the packaging substrate 10, and the disposition area of the packaging substrate 10 needs to be increased, thus causing the size of the semiconductor package 1 to increase.

Therefore, there is a need for a solution that addresses the aforementioned shortcomings of the prior art.

### SUMMARY

In view of the aforementioned shortcomings of the prior art, the present disclosure provides an electronic package, which comprises: a carrier structure having a first side and a second side opposing the first side, wherein the first side is formed with a plurality of conductive pillars electrically connected to the carrier structure; a plurality of first electronic elements bonded on and electrically connected to the first side of the carrier structure; a second electronic element bonded onto the plurality of first electronic elements; an encapsulating layer formed on the first side of the carrier structure and covering the plurality of first electronic elements, the second electronic element and the plurality of conductive pillars; and a circuit structure formed on the encapsulating layer and electrically connected to the plurality of conductive pillars and the second electronic element.

The present disclosure also provides a method of manufacturing an electronic package, the method comprises: providing a carrier structure having a first side and a second side opposing the first side, wherein the first side is formed with a plurality of conductive pillars electrically connected to the carrier structure; disposing an electronic element stacking structure on the first side of the carrier structure, wherein the electronic element stacking structure comprises a plurality of first electronic elements bonded and electrically connected to the carrier structure and a second electronic element bonded to the plurality of first electronic elements; forming an encapsulating layer on the first side of the carrier structure to cover the electronic element stacking structure and the plurality of conductive pillars, wherein end surfaces of the plurality of conductive pillars and the second electronic element are exposed from the encapsulating layer; and forming a circuit structure on the encapsulating layer, wherein the circuit structure is electrically connected to the plurality of conductive pillars and the second electronic element.

In the aforementioned electronic package and method, each of the plurality of first electronic elements has an active surface and an inactive surface opposing the active surface, and the plurality of first electronic elements are all connected to the carrier structure via the active surfaces thereof.

In the aforementioned electronic package and method, each of the plurality of first electronic elements has an active surface and an inactive surface opposing the active surface, and one of the plurality of first electronic elements is connected to the carrier structure via the active surface thereof, and at least one of the plurality of first electronic elements is connected to the carrier structure via the inactive surface thereof.

In the aforementioned electronic package and method, each of the plurality of first electronic elements has an active surface and an inactive surface opposing the active surface, and the plurality of first electronic elements are all connected to the carrier structure via the inactive surfaces thereof.

In the aforementioned electronic package and method, the plurality of first electronic elements are electrically connected to the carrier structure in a flip-chip manner or a wire-bonding manner.

In the aforementioned electronic package and method, the second electronic element is disposed on the plurality of first electronic elements via a bonding layer.

In the aforementioned electronic package and method, the second electronic element has an active surface and an inactive surface opposing the active surface, and a plurality of conductive bumps are formed on the active surface and electrically connected to the circuit structure.

In the aforementioned electronic package and method, a width of the second electronic element is less than an overall layout width of the plurality of first electronic elements.

In the aforementioned electronic package and method, the present disclosure further comprises forming a plurality of solder balls on the second side of the carrier structure.

In the aforementioned electronic package and method, the present disclosure further comprises forming a plurality of conductive elements on the circuit structure.

As can be understood from the above, in the electronic package and manufacturing method thereof of the present disclosure, a variety of chips are integrated into a single package by the design of the electronic element stacking structure, so that the electronic package can meet the requirements for miniaturization without the need to increase the layout area of the carrier structure, and the number of external contacts can also be increased, and bridging can be prevented from occurring between the conductive elements when the electronic package is applied to fine-pitch products.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a manufacturing method of an electronic package of the present disclosure.

FIG. 3 and FIG. 4 are schematic cross-sectional views showing different aspects of FIG. 2E.

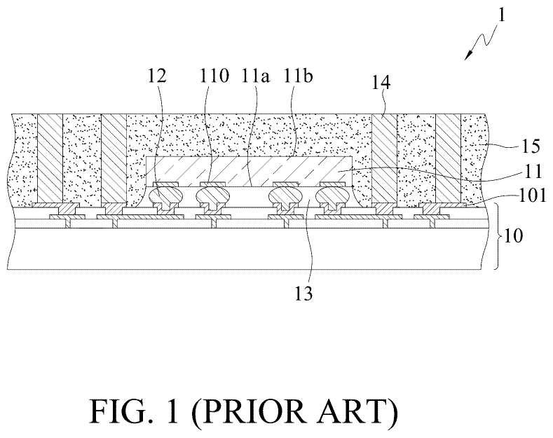

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

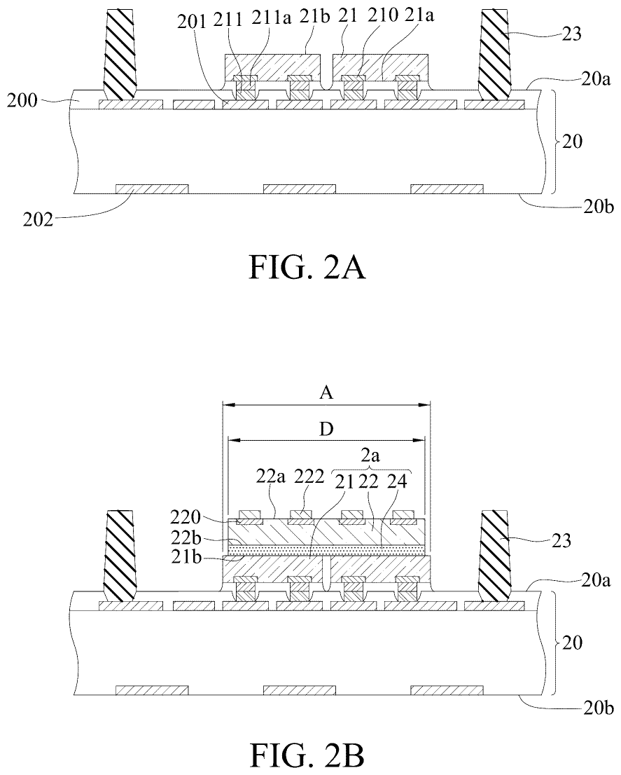

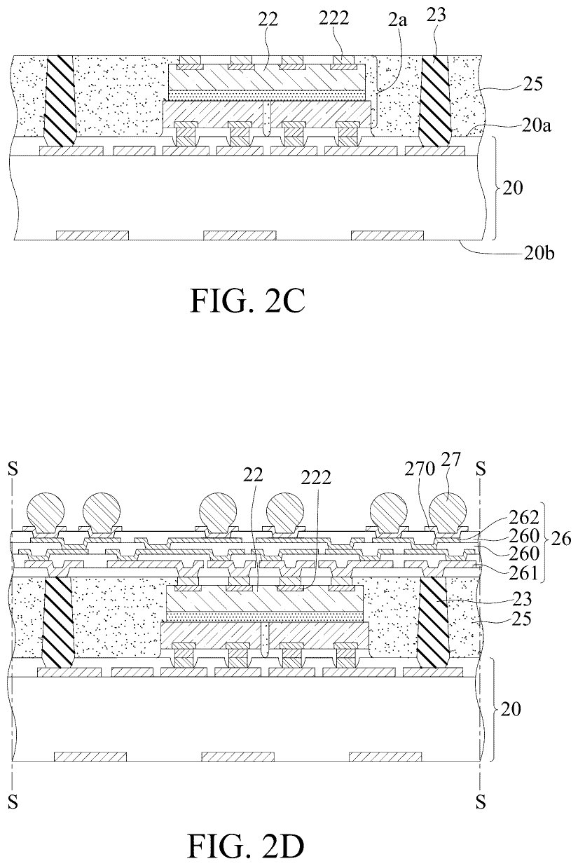

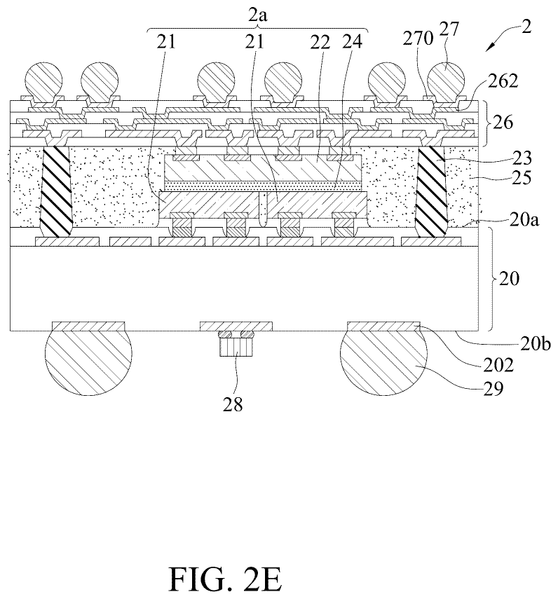

FIG. 2A to FIG. 2E are schematic cross-sectional views illustrating a manufacturing method of an electronic package 2 of the present disclosure.

As shown in FIG. 2A, a carrier structure 20 is provided and has a first side 20a and a second side 20b opposing the first side 20a. A plurality of conductive pillars 23 are formed on the first side 20a, and a plurality of first electronic elements 21 are bonded onto the first side 20a of the carrier structure 20, wherein the first electronic elements 21 are all electrically connected to the carrier structure 20.

The carrier structure 20 is, for example, a packaging substrate with a core layer and a circuit structure, a packaging substrate with a coreless circuit structure, a through-silicon interposer (TSI) with through-silicon vias (TSVs), or a board other than the above. The carrier structure 20 comprises at least one insulating layer and at least one circuit layer bonded to the insulating layer, such as at least one fan-out type redistribution layer (RDL). It should be understood that the carrier structure 20 can also be a plate that carries chips (e.g., the carrier structure 20 can be a lead frame or a wafer), or the carrier structure 20 can be a plate body with metal routings, and the present disclosure is not limited to as such.

In an embodiment, the carrier structure 20 is a packaging substrate and has a plurality of electrical contact pads 201 and an insulating protective layer 200 on the first side 20a thereof, wherein the electrical contact pads 201 are exposed from the insulating protective layer 200, and the second side 20b has a plurality of ball placement pads 202, and the carrier structure 20 has a plurality of circuit layers (not shown) inside to electrically connect the electrical contact pads 201 and the ball placement pads 202. For example, the material forming the electrical contact pads 201 and the ball placement pads 202 is copper, and the material forming the insulating protective layer 200 is solder-resist material or dielectric material such as polybenzoxazole (PBO), polyimide (PI), prepreg (PP), etc.

The conductive pillars 23 are disposed on the electrical contact pads 201 to electrically connect the carrier structure 20, and the conductive pillars 23 are made of metal material (such as copper) or solder material.

The first electronic element 21 is an active element, a passive element, or a combination of the active element and the passive element, wherein the active element is, such as a semiconductor chip, and the passive element is, such as a resistor, a capacitor, or an inductor.

In an embodiment, the first electronic element 21 is a semiconductor chip, such as a microcontroller unit (MCU) or an application specific integrated circuit (ASIC), and the first electronic element 21 has an active surface 21a and an inactive surface 21b opposing the active surface 21a. The active surface 21a has a plurality of electrode pads 210, and the first electronic elements 21 are all electrically connected to the electrical contact pads 201 and the electrode pads 210 in a flip-chip manner (such as by a plurality of solder bumps 211 with copper blocks 211a).

As shown in FIG. 2B, a second electronic element 22 is bonded on the first electronic elements 21, so that the first electronic elements 21 and the second electronic element 22 form an electronic element stacking structure 2a.

The second electronic element 22 is an active element, a passive element, or a combination of the active element and the passive element, wherein the active element is, such as a semiconductor chip, and the passive element is, such as a resistor, a capacitor, or an inductor.

In an embodiment, the second electronic element 22 is a semiconductor chip, such as a dynamic random access memory (DRAM) or a power management IC (PMIC), and the second electronic element 22 has an active surface 22a and an inactive surface 22b opposing the active surface 22a. A plurality of electrode pads 220 are formed on the active surface 22a, and conductive bumps 222 such as copper pillars or solder balls are formed on the electrode pads 220.

Moreover, the inactive surface 22b of the second electronic element 22 is bonded onto the inactive surfaces 21b of the first electronic elements 21 via a bonding layer 24. For example, the bonding layer 24 is first formed on the inactive surface 22b of the second electronic element 22, and then the second electronic element 22 is adhesively fixed onto the first electronic elements 21 on the carrier structure 20. It should be understood that the bonding layer 24 can also be formed on the first electronic elements 21 first, and then the second electronic element 22 is adhesively fixed onto the bonding layer 24. Alternatively, the second electronic element 22 is adhesively fixed on the first electronic elements 21 first, and then the electronic element stacking structure 2a is bonded onto the first side 20a of the carrier structure 20 via the first electronic elements 21. The bonding layer 24 is, such as a film over wire (FOW). In addition, the present disclosure can overcome the height difference that may be caused by different thicknesses of the plurality of first electronic elements 21 by disposing the bonding layer 24 on the inactive surfaces 21b of the first electronic elements 21, so that the second electronic element 22 can be stably disposed onto the plurality of first electronic elements 21.

Also, a width D of the second electronic element 22 is less than an overall layout width A of the first electronic elements 21.

As shown in FIG. 2C, an encapsulating layer 25 is formed on the first side 20a of the carrier structure 20, so that the encapsulating layer 25 covers the electronic element stacking structure 2a and the conductive pillars 23, and then the end surfaces of the conductive pillars 23 and the conductive bumps 222 of the second electronic element 22 are exposed from the encapsulating layer 25 by leveling process.

In an embodiment, the encapsulating layer 25 is made of insulating material, such as polyimide (PI), dry film, encapsulant or molding compound such as epoxy resin. For example, the encapsulating layer 25 may be formed on the first side 20a of the carrier structure 20 in a manner of liquid compound, injection, lamination, or compression molding.

Furthermore, the leveling process removes part of the material of the conductive pillars 23 (part of the material of the conductive bumps 222 can be removed as required) and part of the material of the encapsulating layer 25 in a manner of grinding, so that the end surfaces of the conductive pillars 23 and the conductive bumps 222 of the second electronic element 22 are flush with an upper surface of the encapsulating layer 25.

As shown in FIG. 2D, a circuit structure 26 is formed on the encapsulating layer 25, so that the circuit structure 26 is electrically connected to the conductive pillars 23 and the plurality of conductive bumps 222 of the second electronic element 22, such that the second electronic element 22 can be electrically connected to the first electronic elements 21 via the circuit structure 26, the conductive pillars 23 and the carrier structure 20.

In an embodiment, the circuit structure 26 comprises a plurality of insulating layers 260 and a plurality of redistribution layers (RDLs) 261 formed on the insulating layers 260, and the outermost insulating layer 260 can be served as a solder-resist layer, so that an outermost redistribution layer 262 is exposed from the solder-resist layer for connecting a plurality of conductive elements 27 such as solder bumps. Alternatively, the circuit structure 26 may merely comprise a single insulating layer 260 and a single redistribution layer 261.

Furthermore, the material forming the redistribution layers 261 and 262 is copper, and the material forming the insulating layer 260 is dielectric material such as polybenzoxazole (PBO), polyimide (PI), prepreg (PP).

In addition, an under-bump metallurgy (UBM) layer 270 can be formed on the outermost redistribution layer 262 to facilitate bonding with the conductive elements 27.

As shown in FIG. 2E, a singulation process is performed along a cutting path S shown in FIG. 2D to complete the electronic package 2 of the present disclosure.

In subsequent processes, the electronic package 2 can be connected to an electronic device (not shown) such as a packaging structure or other structures (such as another package or chip) via the conductive elements 27.

Furthermore, the electronic package 2 can also be formed with a plurality of solder balls 29 on the ball placement pads 202 on the second side 20b of the carrier structure 20 for subsequent connection with the electronic device (not shown) such as a packaging structure or other structures (such as a circuit board, another package or chip).

Also, a passive element 28 can be bonded on and electrically connected to the second side 20b of the carrier structure 20.

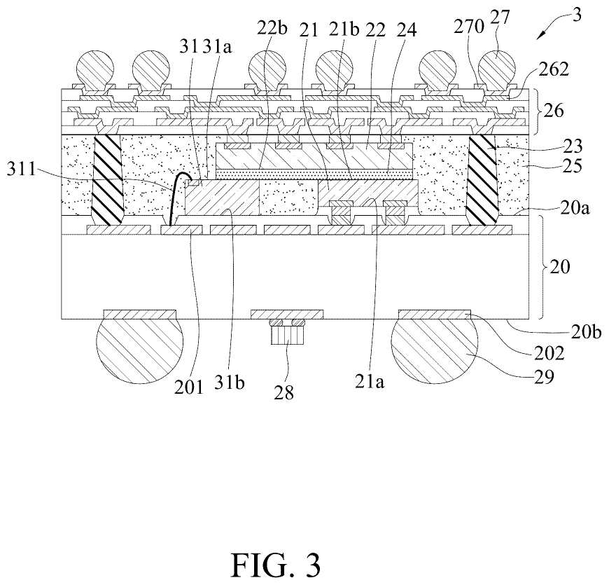

In addition, in an electronic package 3 as shown in FIG. 3, in another embodiment, one of the first electronic elements 21 and 31 can be electrically connected to the carrier structure 20 in a manner of wire bonding. For example, an inactive surface 31b of the first electronic element 31 is disposed on the first side 20a of the carrier structure 20, and the first electronic element 31 is connected to the electrical contact pad 201 via a bonding wire 311. The active surface 21a of the other first electronic element 21 is disposed on the first side 20a of the carrier structure 20, and the inactive surface 22b of the second electronic element 22 is adhesively fixed onto an active surface 31a of the first electronic element 31 and the inactive surface 21b of the first electronic element 21 via the bonding layer 24, wherein the bonding layer 24 may or may not cover the bonding wire 311.

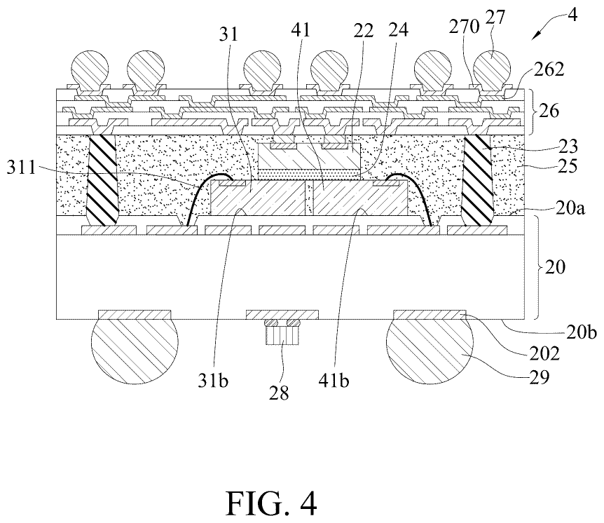

It should be understood that, in an electronic package 4 as shown in FIG. 4, the inactive surface 31b of the first electronic element 31 and an inactive surface 41b of a first electronic element 41 are connected to the carrier structure 20, and the first electronic elements 31, 41 are electrically connected to the carrier structure 20 in a manner of wire bonding.

Therefore, in the manufacturing method of the electronic package 2, 3, 4 of the present disclosure, the electronic element stacking structure 2a is formed by stacking a plurality of chips (i.e., the first electronic elements 21, 31, 41 and the second electronic element 22), so that the electronic package 2, 3, 4 has chips with multiple functions. Therefore, compared with the prior art, the electronic package 2, 3, 4 of the present disclosure can provide more functions without the need to increase the layout area of the first side 20a of the carrier structure 20, such that the requirements of miniaturization for the electronic package 2, 3, 4 can be effectively met.

Furthermore, the contact pads of the circuit structure 26 (i.e., the surface of the redistribution layer 262 exposed from the insulating layer 260) are served as external contacts to facilitate control of the distance between external contacts so as to meet the requirements of fine pitch, and bridging can be prevented from occurring between the conductive elements 27.

The present disclosure also provides an electronic package 2, 3, 4, which comprises: a carrier structure 20, a plurality of first electronic elements 21, 31, 41, a second electronic element 22, an encapsulating layer 25, and a circuit structure 26.

The carrier structure 20 has a first side 20a and a second side 20b opposing the first side 20a, and a plurality of conductive pillars 23 are formed on the first side 20a and electrically connected to the carrier structure 20.

The first electronic elements 21, 31, 41 are bonded and electrically connected to the carrier structure 20.

The second electronic element 22 is bonded onto the plurality of first electronic elements 21, 31, 41.

The encapsulating layer 25 is formed on the first side 20a of the carrier structure 20, so that the encapsulating layer 25 covers the plurality of first electronic elements 21, 31, 41, the second electronic element 22 and the conductive pillars 23, and end surfaces of the conductive pillars 23 and the second electronic element 22 are exposed from the encapsulating layer 25.

The circuit structure 26 is formed on the encapsulating layer 25, and the circuit structure 26 is electrically connected to the conductive pillars 23 and the second electronic element 22.

In one embodiment, each of the plurality of first electronic elements 21 has an active surface 21a and an inactive surface 21b opposing the active surface 21a, and the active surfaces 21a of the plurality of first electronic elements 21 all face the carrier structure 20.

In one embodiment, the first electronic element 21 of one of the plurality of first electronic elements is connected to the carrier structure 20 via an active surface 21a thereof, and at least one first electronic element 31 is connected to the carrier structure 20 via an inactive surface 31b thereof.

In one embodiment, the plurality of first electronic elements 31, 41 are all connected to the carrier structure 20 via the inactive surfaces 31b, 41b thereof.

In one embodiment, at least one of the first electronic elements 21 is electrically connected to the carrier structure 20 in a flip-chip manner.

In one embodiment, at least one of the first electronic elements 31, 41 is electrically connected to the carrier structure 20 in a wire-bonding manner.

In one embodiment, the second electronic element 22 is stacked on the plurality of first electronic elements 21, 31, 41 via a bonding layer 24.

In one embodiment, the second electronic element 22 has a plurality of conductive bumps 222 electrically connected to the circuit structure 26.

In one embodiment, a width D of the second electronic element 22 is less than an overall layout width A of the first electronic elements 21.

In one embodiment, the electronic package 2, 3, 4 further comprises a plurality of solder balls 29 formed on the second side 20b of the carrier structure 20.

In one embodiment, the electronic package 2, 3, 4 further comprises a plurality of conductive elements 27 formed on the circuit structure 26.

In view of the above, in the electronic package and manufacturing method thereof of the present disclosure, a variety of chips are integrated into a single package by the design of the electronic element stacking structure, so that the requirements of miniaturization for the size of the electronic package can be met, and the number of external contacts can also be increased, and bridging can be prevented from occurring between the conductive elements when the electronic package is applied to fine-pitch products.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure having a first side and a second side opposing the first side, wherein the first side is formed with a plurality of conductive pillars electrically connected to the carrier structure;
a plurality of first electronic elements bonded on and electrically connected to the first side of the carrier structure;
a second electronic element bonded onto the plurality of first electronic elements;
an encapsulating layer formed on the first side of the carrier structure and covering the plurality of first electronic elements, the second electronic element and the plurality of conductive pillars; and
a circuit structure formed on the encapsulating layer and electrically connected to the plurality of conductive pillars and the second electronic element.

2. The electronic package of claim 1, wherein each of the plurality of first electronic elements has an active surface and an inactive surface opposing the active surface, and the plurality of first electronic elements are all connected to the carrier structure via the active surfaces thereof.

3. The electronic package of claim 1, wherein each of the plurality of first electronic elements has an active surface and an inactive surface opposing the active surface, and one of the plurality of first electronic elements is connected to the carrier structure via the active surface thereof, and at least one of the plurality of first electronic elements is connected to the carrier structure via the inactive surface thereof.

4. The electronic package of claim 1, wherein each of the plurality of first electronic elements has an active surface and an inactive surface opposing the active surface, and the plurality of first electronic elements are all connected to the carrier structure via the inactive surfaces thereof.

5. The electronic package of claim 1, wherein the plurality of first electronic elements are electrically connected to the carrier structure in a flip-chip manner or a wire-bonding manner.

6. The electronic package of claim 1, wherein the second electronic element is disposed on the plurality of first electronic elements via a bonding layer.

7. The electronic package of claim 1, wherein the second electronic element has an active surface and an inactive surface opposing the active surface, and a plurality of conductive bumps are formed on the active surface and electrically connected to the circuit structure.

8. The electronic package of claim 1, wherein a width of the second electronic element is less than an overall layout width of the plurality of first electronic elements.

9. The electronic package of claim 1, further comprising a plurality of solder balls formed on the second side of the carrier structure.

10. The electronic package of claim 1, further comprising a plurality of conductive elements formed on the circuit structure.

11. A method of manufacturing an electronic package, comprising:
providing a carrier structure having a first side and a second side opposing the first side, wherein the first side is formed with a plurality of conductive pillars electrically connected to the carrier structure;
disposing an electronic element stacking structure on the first side of the carrier structure, wherein the electronic element stacking structure comprises a plurality of first electronic elements bonded and electrically connected to the carrier structure and a second electronic element bonded to the plurality of first electronic elements;
forming an encapsulating layer on the first side of the carrier structure to cover the electronic element stacking structure and the plurality of conductive pillars, wherein end surfaces of the plurality of conductive pillars and the second electronic element are exposed from the encapsulating layer; and
forming a circuit structure on the encapsulating layer, wherein the circuit structure is electrically connected to the plurality of conductive pillars and the second electronic element.

12. The method of claim 11, wherein each of the plurality of first electronic elements has an active surface and an inactive surface opposing the active surface, and the plurality of first electronic elements are all connected to the carrier structure via the active surfaces thereof.

13. The method of claim 11, wherein each of the plurality of first electronic elements has an active surface and an inactive surface opposing the active surface, and one of the plurality of first electronic elements is connected to the carrier structure via the active surface thereof, and at least one of the plurality of first electronic elements is connected to the carrier structure via the inactive surface thereof.

14. The method of claim 11, wherein each of the plurality of first electronic elements has an active surface and an inactive surface opposing the active surface, and the plurality of first electronic elements are all connected to the carrier structure via the inactive surfaces thereof.

15. The method of claim 11, wherein the plurality of first electronic elements are electrically connected to the carrier structure in a flip-chip manner or a wire-bonding manner.

16. The method of claim 11, wherein the second electronic element is disposed on the plurality of first electronic elements via a bonding layer.

17. The method of claim 11, wherein the second electronic element has an active surface and an inactive surface opposing the active surface, and a plurality of conductive bumps are formed on the active surface and electrically connected to the circuit structure.

18. The method of claim 11, wherein a width of the second electronic element is less than an overall layout width of the plurality of first electronic elements.

19. The method of claim 11, further comprising forming a plurality of solder balls on the second side of the carrier structure.

20. The method of claim 11, further comprising forming a plurality of conductive elements on the circuit structure.
